(19) United States
(12) Patent Application Publication
(10) Pub. No.: US 2013/0293751 A1
(43) Pub. Date: Nov. 7, 2013

(54) IMAGING SYSTEMS WITH SEPARATED COLOR FILTER ELEMENTS

(71) Applicant: APTINA IMAGING CORPORATION, George Town (KY)

(72) Inventors: Brian Vaartstra, Nampa, ID (US); Swarnal Borthakur, Boise, ID (US); Marc Sulfridge, Boise, ID (US)

(73) Assignee: Aptina Imaging Corporation, George Town (KY)

(21) Appl. No.: 13/875,905

(22) Filed: May 2, 2013

Related U.S. Application Data
(60) Provisional application No. 61/642,387, filed on May 3, 2012.

(51) Int. Cl. H01L 27/146; H01L 31/18; H04N 9/04

(52) U.S. Cl. CPC H01L 27/14625; H04N 9/045; H01L 27/14627; H01L 31/18
USPC 348/280; 250/208.1; 438/70

(57) ABSTRACT

An image sensor may be provided with an array of imaging pixels. A color filter array may be formed over photosensitive elements in the pixel array. The color filter array may include a Bayer color filter array. Separating material may be interposed between color filter elements of adjacent imaging pixels. The separating material may be relatively low index of refraction material configured to reduce or eliminate optical crosstalk between adjacent imaging pixels. The separating material may be air so that neighboring color filter elements are separated by an air gap. The air gaps may be formed during the color filter array fabrication process by depositing a sacrificial layer on the substrate, forming openings in the sacrificial layer, forming color filter elements in the openings, and removing remaining portions of the sacrificial layer that are formed between the color filter elements.

This application claims the benefit of provisional patent application No. 61/642,387, filed May 3, 2012, which is hereby incorporated by reference herein in its entirety.

### BACKGROUND

This relates generally to imaging devices, and more particularly, to imaging devices with color filter arrays.

Modern electronic devices such as cellular telephones, cameras, and computers often use digital image sensors. Imagers (i.e., image sensors) may be formed from a two-dimensional array of image sensing pixels. Each pixel may include a photosensor such as a photodiode that receives incident photons (light) and converts the photons into electrical signals. Image sensors are sometimes designed to provide images to electronic devices using a Joint Photographic Experts Group (JPEG) format or any other suitable image format.

Imagers may be provided with color filter arrays. A color filter array may include an array of color filter elements formed over an array of photosensors. Each color filter element in the color filter array may be optimized to pass a light having a given wavelength band. For example, a color filter array may include red color filters which are optimized to pass a wavelength band corresponding to red light, blue color filters which are optimized to pass a wavelength band corresponding to blue light, and green color filters which are optimized to pass a wavelength band corresponding to green light. Various interpolation and signal processing schemes may be used to construct a full-color image using the image data which is gathered from an imager having a color filter array.

In a typical color filter array, adjacent color filter elements are formed in contact with each other and can sometimes be partially overlapping color filter elements. However, contacting and partially overlapping color filter elements can allow light to pass through a color filter element of one pixel onto a photosensor of an adjacent pixel, generating undesirable optical cross-talk. In some cases, a light-absorbing barrier is formed between adjacent color filter elements. Light-absorbing barriers of this type may help prevent cross-talk, however, if care is not taken, this type of barrier can reduce the quantum efficiency of each pixel, thereby reducing the signal-to-noise level of image data captured by this type of system.

It would therefore be desirable to be able to provide improved imaging devices with color filter arrays.

### BRIEF DESCRIPTION OF THE DRAWINGS

FIG. 1 is a diagram of an illustrative electronic device having an image sensor with a color filter array in accordance with an embodiment of the present invention.

FIG. 2 is a top view of a portion of an illustrative pixel array having imaging pixels in accordance with an embodiment of the present invention.

FIG. 3 is a cross-sectional side view of a portion of a conventional pixel array exhibiting optical crosstalk between adjacent pixels.

FIG. 4 is a cross-sectional side view of a portion of an illustrative pixel array having separated color filter elements in accordance with an embodiment of the present invention.

FIG. 5 is a top view of a portion of an illustrative pixel array having imaging pixels with microlenses over a color filter array with separated color filter elements in accordance with an embodiment of the present invention.

FIG. 6 is a flow diagram showing process steps involved in forming an illustrative color filter array with separated color filter elements in accordance with an embodiment of the present invention.

FIG. 7 is a flowchart of illustrative steps involved in forming an illustrative color filter array having separated color filter elements in accordance with an embodiment of the present invention.

FIG. 8 is a block diagram of an illustrative imager having a color filter array with separated color filter elements in accordance with an embodiment of the present invention.

### DETAILED DESCRIPTION

Electronic devices such as digital cameras, computers, cellular telephones, and other electronic devices include image sensors that gather incoming light to capture an image. The image sensors may include arrays of imaging pixels. The pixels in the image sensors may include photosensitive elements such as photodiodes that convert the incoming light into image signals. Image sensors may have any number of pixels (e.g., hundreds or thousands or more). A typical image sensor may, for example, have hundreds of thousands or millions of pixels (e.g., megapixels). Image sensors may include control circuitry such as circuitry for operating the imaging pixels and readout circuitry for reading out image signals corresponding to the electric charge generated by the photosensitive elements.

Image sensors may be provided with color filter arrays having color filter elements that are separated by intervening low index of refraction material such as air. Color filter arrays having separated color filter elements may be provided for complementary metal-oxide-semiconductor (CMOS) image sensors or charge-coupled device (CCD) image sensors. Image sensors may be front-side illumination (FSI) image sensors or backside illumination (BSI) image sensors.

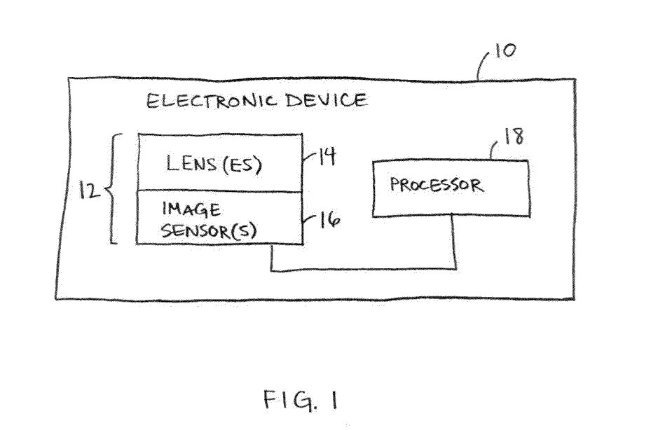

FIG. 1 is a diagram of an illustrative electronic device that uses an image sensor to capture images. Electronic device 10 of FIG. 1 may be a portable electronic device such as a camera, a cellular telephone, a video camera, or other imaging device that captures digital image data. Camera module 12 may be used to convert incoming light into digital image data. Camera module 12 may include one or more lenses 14 and one or more corresponding image sensors 16. During image capture operations, light from a scene may be focused onto image sensor 16 by lens 14. Image sensor 16 provides corresponding digital image data to processing circuitry 18. Image sensor 16 may, for example, be a backside illumination image sensor. If desired, camera module 12 may be provided with an array of lenses 14 and an array of corresponding image sensors 16.

Image sensor 16 may include an array of image sensor pixels and a corresponding array of color filter elements. Each color filter element may be separated from neighboring color filter elements by a separating material having a relatively low index of refraction in comparison with the index of refraction of the color filter element. In one suitable example that is sometimes discussed herein as an example, neighboring color filter elements may be separated by an air gap between the color filter elements. The change in the index of refraction between the color filter element and the separating material (e.g., the air) may have a light-piping effect that helps prevent light that has entered a particular color filter element from exiting that color filter element and reaching the photosensitive element of a neighboring pixel.

Processing circuitry 18 may include one or more integrated circuits (e.g., image processing circuits, microprocessors, storage devices such as random-access memory and non-volatile memory, etc.) and may be implemented using components that are separate from camera module 12 and/or that form part of camera module 12 (e.g., circuits that form part of an integrated circuit that includes image sensors 16 or an integrated circuit within module 12 that is associated with image sensors 16). Image data that has been captured by camera module 12 may be processed and stored using processing circuitry 18. Processed image data may, if desired, be provided to external equipment (e.g., a computer or other device) using wired and/or wireless communications paths coupled to processing circuitry 18.

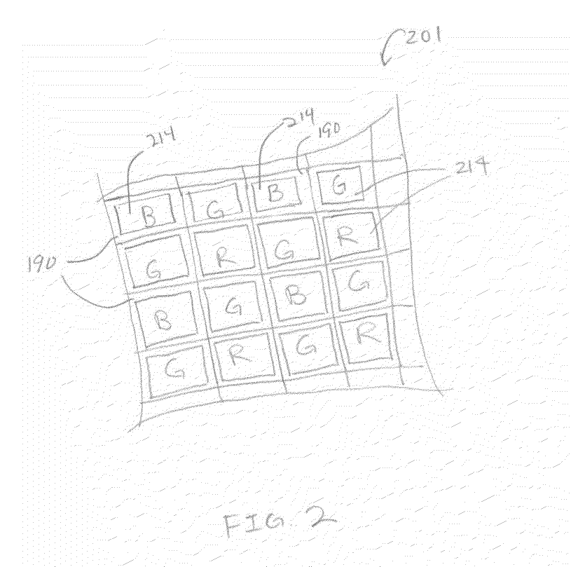

As shown in FIG. 2, image sensor 16 may include a pixel array such as pixel array 201 (top view) containing imaging pixels such as image sensor pixels 190. Imaging pixels 190 may be configured to gather image data to be used in generating images of a scene. The term “imaging pixel” may be used to describe a pixel that gathers color image data to be used in generating images of a real-world scene.

Pixel array 201 may include imaging pixels 190 arranged in rows and columns. Each imaging pixel 190 may include an associated imaging pixel circuit. A filter such as color filter element 214 may be formed over each imaging pixel 190 in array 201. In the example of FIG. 2, color filter elements 214 are formed in a Bayer pattern of red color filter elements, blue color filter elements, and green color filter elements. This is, however, merely illustrative. If desired, color filters 214 may be formed in a cyan-magenta-yellow-key pattern, all color filters 214 may have a common color, or color filter elements 214 may be provided in any other suitable pattern. Array 201 may contain, for example, hundreds or thousands of rows and columns of image sensor pixels 190.

Control circuitry may be used to supply control signals such as reset, transfer, and read control signals to pixels 190. Control circuitry including sample-and-hold circuitry, amplifier circuitry, analog-to-digital conversion circuitry, bias circuitry such as pixel column bias supply circuits (e.g., circuitry such as current mirror circuitry for providing bias currents to source follower transistors of pixels 190), memory or other circuitry for operating pixels 190. Image data from imaging pixels 190 having separated color filter elements may be gathered during pixel readout operations and may be subsequently used to generate an image of a real-world scene.

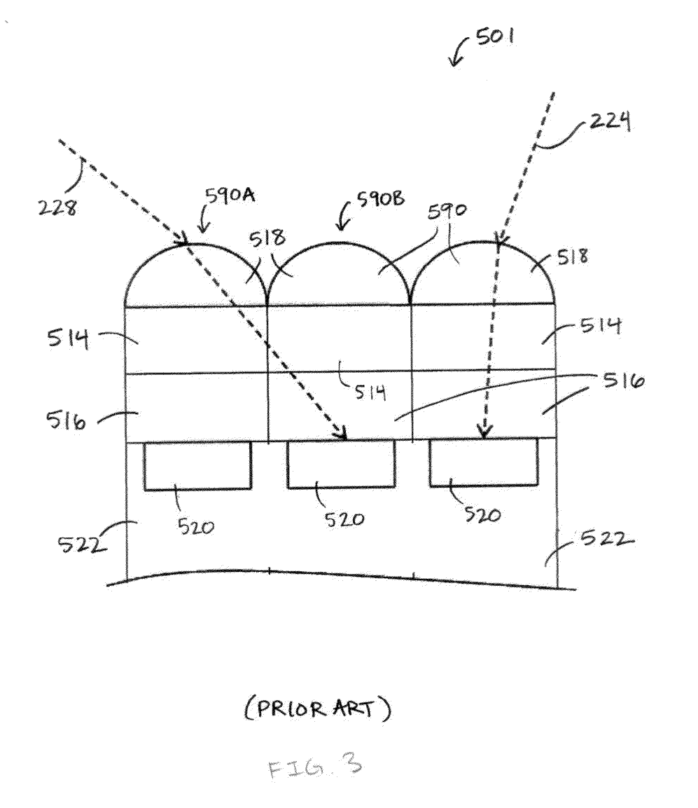

FIG. 3 shows a cross-section of a portion of a conventional pixel array 501 having pixels 590. Pixels 590 include microlens 518, color filter 514, dielectric layer 516, and photodiodes 520 formed in substrate layer 522.

Each microlens 518 directs incident light towards an associated photodiode 520. As shown in FIG. 3, incident light 224 is directed by microlens 518 towards photodiode 520. Photodiode 520 absorbs incident light focused by microlens 518 and produces image signals that correspond to the amount of incident light absorbed.

In this type of configuration, some light can pass through the color filter of a first pixel and strike the photodiode of a second pixel (e.g., a pixel that is adjacent to the first pixel). As shown in FIG. 3, incident light 228 passes through color filter 514 of pixel 590A onto photodiode 520 of pixel 590B. This type of “light leakage” is often referred to as optical crosstalk. If care is not taken, optical crosstalk can degrade the quality of images produced by an image sensor.

Optical crosstalk may sometimes be accounted for during image processing (e.g., during the color interpolation process). Color interpolation techniques which are specific to a Bayer imaging array have been developed which may be used to reduce the effects of optical crosstalk in a Bayer imaging array. However, color interpolation techniques do not address the problem of optical crosstalk at the level of the image capturing process, which must be addressed to improve overall signal-to-noise level. If care is not taken, optical crosstalk between pixels may degrade the quality of an image produced by pixels 190 and/or affect the proper function of other types of pixels.

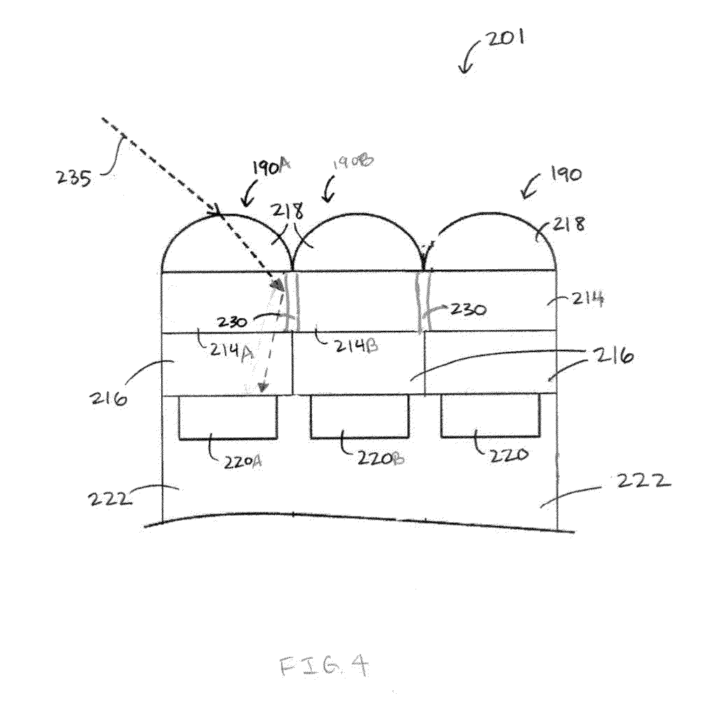

A cross-sectional side view of a portion of array 201 having separated color filters that help prevent optical crosstalk is shown in FIG. 4. Pixels 190 may include microlens 218, color filters 214, an optional stack of dielectric layers 216, and a photosensitive region such as photosensitive region 220 formed in substrate layer 222. Each microlens 218 may direct incident light onto an associated photosensitive region 220 through an associated color filter element 214.

As shown in FIG. 4, color filter elements 214 may be separated from each other by a color filter separation element such as material 230. Color filter separation elements 230 (sometimes referred to as color filter dividers) may be interposed between neighboring imaging pixels 190 to help prevent optical crosstalk. Color filter separation elements 230 may be formed from any suitable material having a relatively low index of refraction (sometimes referred to herein as a refractive index). To maximize the quantum efficiency of each pixel, thereby maximizing the signal-to-noise ratio in image data generated by pixels 190 while preventing optical crosstalk, it may be desirable to separate color filter elements 214 using materials 230 with a low refractive index (R.I.) such as materials with a refractive index less than 1.3, less than 1.5, between 1.0 and 1.3, between 1.0 and 1.5, between 1.29 and 1.31, between 1.4 and 1.5 (as examples). In one suitable configuration that is sometimes described herein as an example separating material 230 may be air (i.e., color filter elements 214 may separated from each other by air gaps between the color filter elements).

In configurations in which gaps between neighboring color filter elements 214 are filled with a material other than air, the refractive index of material 230 may depend on the size of pixels 190. For example, the pixel size of pixels 190 may be 1-2 μm, 1-6 μm, less than 10 μm, less than 2 μm, less than 1.5 μm, etc. In configurations in which pixels 190 have a width of between 1.0 microns and 1.4 microns, material 230 may have a refractive index between 1.0 and 1.5. The width of the gaps between color filter elements 214 may be customized and optimized based on the characteristics and desired performance of the imaging array in which color filter separation elements 230 are used.

As shown in FIG. 4, incident light such as incident light 235 may strike microlens 218 of pixel 190A at a high angle of incidence and may be initially directed towards adjacent pixel 190B. Due to the change in refractive index at the interface of color filter element 214A and material 230, light 235 may be reflected back onto photosensitive element 220A rather than travelling through adjacent color filter element 214B onto photosensitive element 220B.

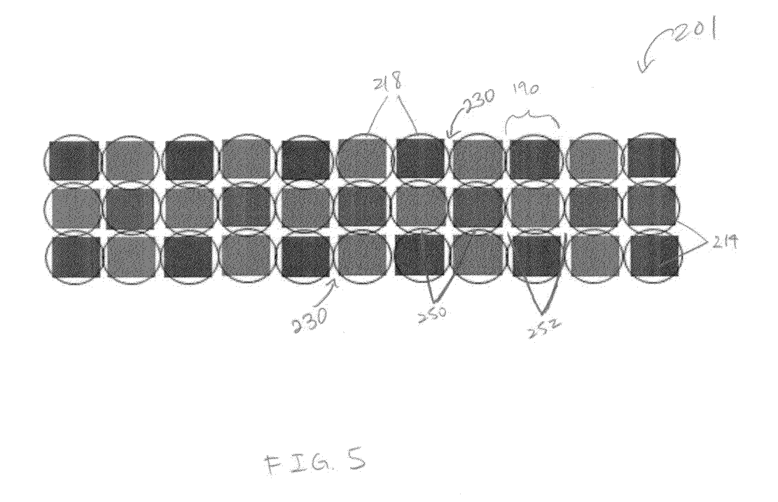

In FIG. 5, a top view of pixel array 201 shows how a microlens may be formed over color filter element 214 of each pixel 190 in the array. Pixel array 201 may include imaging pixels 190 arranged in rows and columns. A color filter such as color filters 214 may be formed over each imaging pixel 190.

Microlenses 218 may include contacting portions such as overlapping regions 250 that contact microlenses 218 of adjacent pixels. The array of microlenses may also include openings between microlenses 218 such as openings 252.

During manufacturing operations, microlenses 218 may be formed on color filter elements 214 prior to formation of color filter separation elements 230 between the color filter elements. In order to form air gaps 230 (or gaps filled with other materials) between color filter elements 214, openings 252 in the array of microlenses that allow access to structures under microlenses 218 may be provided for the formation of material 230 between the color filter elements. For example, a wet chemical bath may flow through openings 252 to remove materials formed under microlenses 218, creating air gaps such as air gaps 230 in the color filter array.

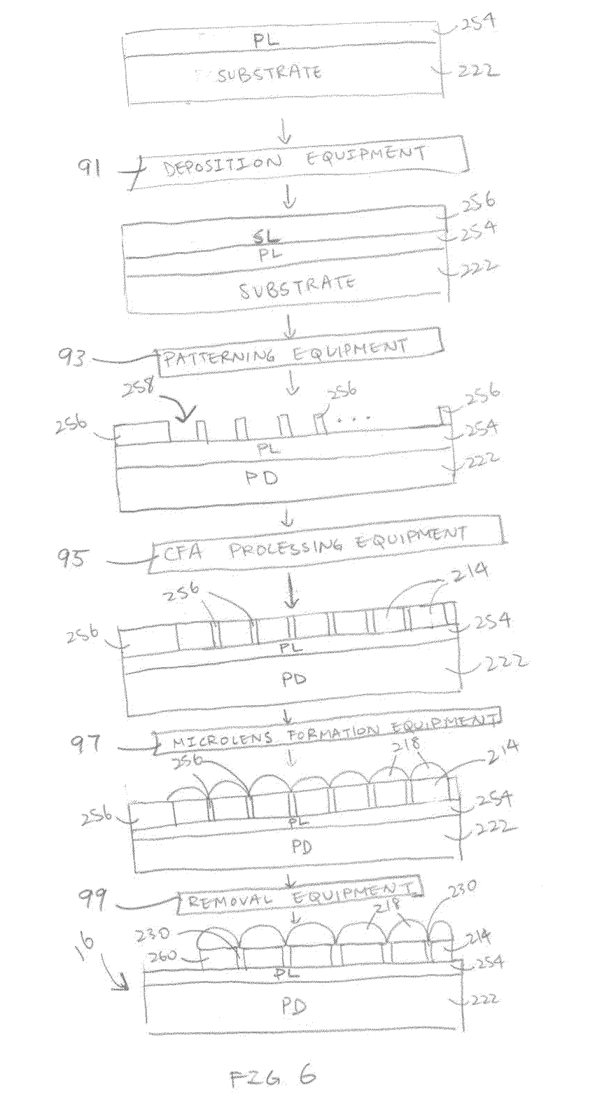

FIG. 6 is a diagram showing illustrative process steps that may be involved in forming a pixel array such as pixel array 201 with color filter separation elements such as air gaps 230 between adjacent color filter elements 214.

As shown in FIG. 6, a substrate layer such as substrate layer 222 with a top surface covered with a protective coating such as passivation layer 254 may be obtained. Substrate layer 222 may include photosensitive regions such as photosensitive regions 220 (see, e.g., FIG. 4) that absorb light and produce image signals that correspond to the amount of light absorbed.

After the coated substrate layer is obtained, deposition equipment 91 may be used to deposit a layer such as sacrificial layer 256 on top of passivation layer 254. Sacrificial layer 256 may be formed from an oxide material such as silicon oxide and phosphorous and/or boron-doped silicon oxide (e.g., borophosphosilicate glass).

Patterning equipment 93 may then be used to pattern sacrificial layer 256 to form openings such as wells 258 in layer 256. Wells 258 may be defined by side walls formed by remaining patterned portions of sacrificial layer 256 and a bottom surface formed by passivation layer 254. Wells 258 in sacrificial layer 256 may be aligned with the photosensitive regions in substrate layer 222. Openings 258 may be formed in layer 256 using any suitable semiconductor processing method, including using dry and/or wet etching techniques, either alone or in combination with photolithographic techniques.

Color filter array (CFA) processing equipment 95 may be used to print color filter array material into wells 258 to form color filter elements 214. At this stage, individual color filter elements 214 may be separated by remaining portions of sacrificial layer 256. Color filter elements 214 may be formed such that they are aligned with photosensitive regions such as regions 220 in substrate layer 222 for each individual pixel.

Microlens formation equipment 97 may then be used to form microlenses 218 above each color filter element 214. Microlenses 218 may partially overlap each other as described above in connection with the top view shown in FIG. 5.

After the formation of microlenses 218 above color filters 214, removal equipment 99 (e.g., patterning, etching, or other suitable equipment) may be used to remove the remaining portions of sacrificial layer 256 that are interposed between each individual adjacent color filter 214. Removal of the remaining portions of sacrificial layer 256 forms air gaps 230 between each color filter 214. Removal equipment 99 may include any equipment suitable for removing portions of sacrificial layer 256, including physical removal equipment or chemical removal equipment. In one suitable example, removal equipment 99 may include equipment for exposing material 256 to a wet bath of materials with chemical properties that are highly selective in removing the material that forms sacrificial layer 256. For example, a diluted hydrogen fluoride chemical bath that is highly selective in removing oxide in the presence of organic color filter array material and microlens materials may be used.

If desired, air gaps 230 may then be filled with other low index of refraction material. However, this is merely illustrative. If desired, image sensor 16 may be provided with air gaps between color filter elements 214.

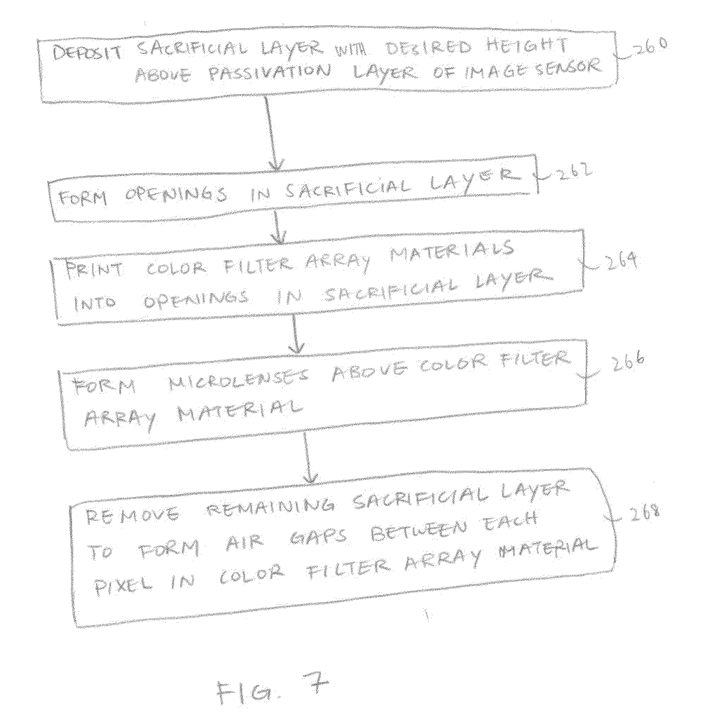

FIG. 7 is a flow chart of illustrative steps involved in forming a color filter array having air gaps that reduce or eliminate optical crosstalk on an image sensor.

At step 260, a sacrificial layer such as sacrificial layer 256 of FIG. 6 may be deposited on a passivation layer on an image sensor integrated circuit substrate containing photosensitive components (e.g., photodiodes). Sacrificial layer 256 may be deposited with any desired height or thickness above the passivation layer. Sacrificial layer 256 may be formed from an oxide material or any other suitable material for forming containers that may be filled with color filter array materials. For example, sacrificial layer 256 may be formed from silicon oxide or phosphorous and/or boron-doped silicon oxide (e.g., borophosphosilicate glass).

At step 262, openings such as wells 258 of FIG. 6 may be formed in sacrificial layer 256 by removing portions of sacrificial layer 256 that are aligned with the photosensitive components of the substrate layer. The openings may be formed by any suitable removal technique, including dry and wet etching processes, either alone or in combination with photolithography.

At step 264, color filter array materials such as colored photoresistive materials may be formed in the openings of the sacrificial layer to form color filter elements such as color filters 214 of FIG. 6. Forming color filter array materials into openings of the sacrificial layer such as wells 258 may include depositing photodefinable material of a first color into the wells, removing the first color photodefinable material from some of the wells, depositing photodefinable materials of a second color into unfilled wells, removing the second color photodefinable materials from some of the wells, depositing photodefinable materials of a third color into unfilled wells, and removing portions of the third color photodefinable materials. The depositing of colored photodefinable material (i.e. color filter array material) may be performed in any suitable order and may include any suitable combination of colors. For example, the first color may be green, the second color may be red, and the third color may be blue.

An optional planarizing layer may be deposited above the color filter materials to even out or smooth the top surfaces of the deposited color filter array materials at step 264, if desired. The planarizing layer may be formed from transparent material and composed of materials similar to materials that form microlenses. Chemical-mechanical polishing/planarization (CMP) or photolithography operations may be performed to remove portions of the planarizing layer to expose the top surfaces of remaining portions of sacrificial layer 256 (i.e., the tops of sidewalls of wells 258).

At step 266, microlenses such as microlenses 218 may be formed above the color filter array material. Microlenses 218 may be formed such that they overlap in some regions while leaving spaces for access to portions of the sacrificial layer that may be removed. Microlenses 218 may be formed using any suitable process, including dry etching.

At step 268, the remaining portions of the sacrificial layer may be removed to form color filter separation elements such as air gaps 230 of, for example, FIG. 4 between each color filter element. The sacrificial layer may be removed using any suitable physical or chemical techniques, such as a wet bath of chemicals that selectively removes the material that forms sacrificial layer 256. For example, a diluted hydrogen fluoride chemical bath that is highly selective to removing oxide that forms the sacrificial layer in the presence of organic color filter array material and microlens materials may be used.

Prior to removing the remaining portions of sacrificial layer 256, a resist coating that is resistant to damage from the removal chemicals (e.g. resistant to wet hydrogen fluoride) may be applied over any exposed regions of substrate 222 containing electronic structures and components that may be prone to damage by the removal chemicals (e.g. aluminum bond pads).

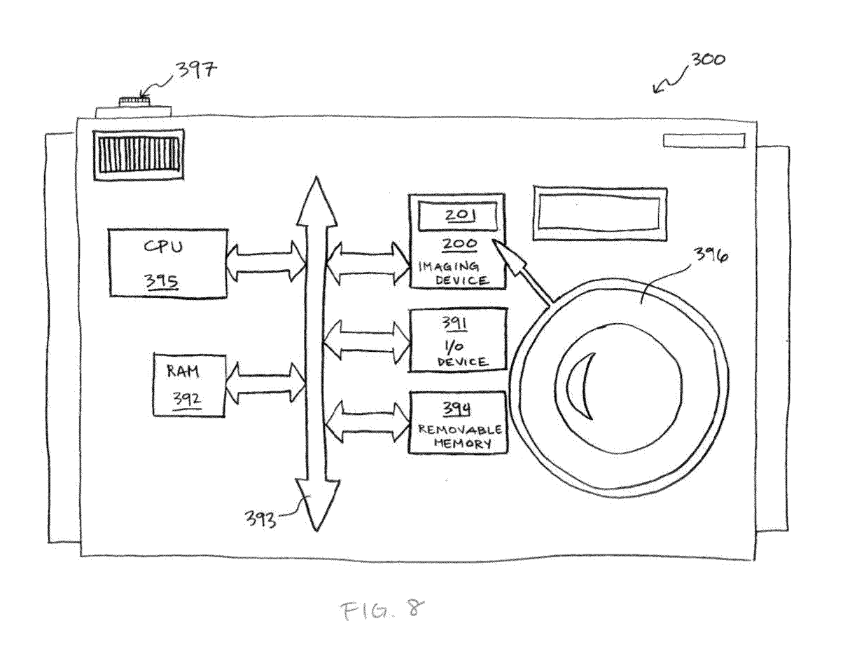

FIG. 8 shows in simplified form a typical processor system 300, such as a digital camera, which includes an imaging device 200. Imaging device 200 may include a pixel array 201 of the type shown in FIG. 2 having separated color filter elements as described above. Processor system 300 is exemplary of a system having digital circuits that may include imaging device 200. Without being limiting, such a system may include a computer system, still or video camera system, scanner, machine vision, vehicle navigation, video phone, surveillance system, auto focus system, star tracker system, motion detection system, image stabilization system, and other systems employing an imaging device.

Processor system 300, which may be a digital still or video camera system, may include a lens such as lens 396 for focusing an image onto a pixel array such as pixel array 201 when shutter release button 397 is pressed. Processor system 300 may include a central processing unit such as central processing unit (CPU) 395. CPU 395 may be a microprocessor that controls camera functions and one or more image flow functions and communicates with one or more input/output (I/O) devices 391 over a bus such as bus 393. Imaging device 200 may also communicate with CPU 395 over bus 393. System 300 may include random access memory (RAM) 392 and removable memory 394. Removable memory 394 may include flash memory that communicates with CPU 395 over bus 393. Imaging device 200 may be combined with CPU 395, with or without memory storage, on a single integrated circuit or on a different chip. Although bus 393 is illustrated as a single bus, it may be one or more buses or bridges or other communication paths used to interconnect the system components.

Various embodiments have been described illustrating image sensors that have color filter arrays with separated color filter elements. Image sensors with color filter separation elements of this type may be used in an electronic device.

An image sensor may have a pixel array which includes imaging pixels. To reduce optical crosstalk between adjacent imaging pixels, color filter separation elements such as air gaps or gaps that are filled with other low refractive index materials may be formed between neighboring color filter elements of neighboring imaging pixels.

During manufacturing, a color filter array having separated color filter elements may be formed on an image sensor integrated circuit substrate by depositing a sacrificial layer of material on the substrate, forming openings in the sacrificial layer, forming color filter elements in the openings, and removing remaining portions of the sacrificial layer that are formed between the color filter elements. In this way, air gaps may be formed between neighboring color filter elements.

If desired, the air gaps may then be filled with additional separating material such as material having a refractive index less than 1.5.

The foregoing is merely illustrative of the principles of this invention which can be practiced in other embodiments.

What is claimed is:

1. An image sensor, comprising:
a substrate;
an array of photosensitive elements on the substrate; and
an array of corresponding color filter elements, wherein each color filter element in the array of corresponding color filter elements is separated from at least one neighboring color filter element in the array of corresponding color filter elements by an air gap.

2. The image sensor defined in claim 1 wherein each color filter element in the array of corresponding color filter elements is formed over an associated photosensitive element in the array of photosensitive elements.

3. The image sensor defined in claim 2 wherein each photosensitive element and each corresponding color filter element form a portion of an imaging pixel having a width of less than 1.5 microns.

4. The image sensor defined in claim 2 wherein the array of corresponding color filter elements comprises a Bayer pattern array of color filter elements.

5. The image sensor defined in claim 2, further comprising:
a plurality of microlenses arranged over the array of corresponding color filter elements, wherein each microlens in the plurality of microlenses is configured to focus light onto a respective photosensitive element in the array of photosensitive elements through a color filter element in the array of corresponding color filter elements.

6. The image sensor defined in claim 5, further comprising a passivation layer between the array of corresponding color filter elements and the substrate.

7. The image sensor defined in claim 6 wherein the plurality of microlenses includes portions that partially cover the air gap.

8. A method for forming a color filter array for an image sensor, comprising:
obtaining a substrate having a passivation layer on the substrate;
depositing a sacrificial layer on the passivation layer;
forming openings in the deposited sacrificial layer;
forming color filter elements in the openings; and
removing remaining portions of the sacrificial layer to form air gaps between adjacent color filter elements.

9. The method defined in claim 8 wherein forming openings in the deposited sacrificial layer comprises removing portions of the deposited sacrificial layer that are aligned with photosensitive regions in the substrate.

10. The method defined in claim 9 wherein forming the color filter elements in the openings comprises:
forming color filter elements of a first color in a first subset of the openings;
forming color filter elements of a second color in a second subset of the openings; and
forming color filter elements of a third color in a third subset of the openings.

11. The method defined in claim 10 wherein forming the color filters of the first color in the first subset of the openings comprises depositing and patterning photodefinable material of the first color.

12. The method defined in claim 11 wherein removing the remaining portions of the sacrificial layer comprises applying a chemical bath that selectively removes the remaining portions of the sacrificial layer.

13. The method defined in claim 12, further comprising:
prior to applying the chemical bath, applying a resist coating that is resistant to damage from the chemical bath over regions of the substrate.

14. The method defined in claim 12 wherein applying the chemical bath comprises applying a hydrogen fluoride chemical bath.

15. The method defined in claim 8, further comprising forming microlenses over the color filter elements.

16. The method defined in claim 15, further comprising forming additional material in the air gaps.

17. The method defined in claim 16 wherein the additional material has a refractive index of less than 1.5.

18. The method defined in claim 8 wherein the sacrificial layer comprises an oxide material.

19. The method defined in claim 18 wherein the oxide material comprises silicon oxide.

20. The method defined in claim 19 wherein the oxide material comprises phosphorous-doped silicon oxide.

21. The method defined in claim 19 wherein the oxide material comprises boron-doped silicon oxide.

22. The method defined in claim 18 wherein the oxide material comprises borophosphosilicate glass.

23. A system, comprising:
a central processing unit;
memory;
input-output circuitry; and
an imaging device, wherein the imaging device comprises:
a pixel array having a plurality of imaging pixels;
a lens that focuses light onto the pixel array; and
a color filter array having a plurality of color filter dividers, wherein each color filter divider is interposed between neighboring color filter elements in the color filter array, and wherein each color filter divider comprises material having a refractive index of less than 1.5.

24. The system defined in claim 23 wherein the imaging device further comprises a plurality of microlenses each associated with a selected one of the plurality of imaging pixels.

25. The system defined in claim 23 wherein the imaging pixels comprise backside illumination image pixels.
